(19) United States
(12) Patent Application Publication
(10) Pub. No.: US 2019/0189472 A1
(43) Pub. Date: Jun. 20, 2019

(54) PFA TUBE HEATER WITH FLEXIBLE HEATING ELEMENTS

(71) Applicant: Trebor International, West Jordan, UT (US)

(72) Inventors: Larry S. Dunbar, Riverton, UT (US); Cory Dennis Shorr, South Jordan, UT (US)

(21) Appl. No.: 16/218,222

(22) Filed: Dec. 12, 2018

Related U.S. Application Data
(60) Provisional application No. 62/607,237, filed on Dec. 18, 2017.

(51) Int. Cl. H01L 21/67; H05B 3/64

(52) U.S. Cl. CPC H01L 21/67103; F24H 1/142; H05B 3/64

(57) ABSTRACT

One example of a tube heater includes a fluid conduit, a heating element that is at least partly made of carbon and is in thermal communication with the fluid conduit, one or more conductors that are in electrical communication with the heating element and are configured to provide power to the heating element, an electrical insulator configured and arranged to electrically isolate the heating element from the one or more conductors, and a containment tube within which the fluid conduit, heating element, conductors, and electrical insulator are disposed.

### RELATED APPLICATIONS

This application hereby claims priority to U.S. Provisional Patent Application, Ser. 62/607,237, entitled PEA TUBE HEATER WITH FLEXIBLE HEATING ELEMENTS, and filed Dec. 18, 2017 (the '237 Application). All of the aforementioned applications are incorporated herein in their respective entireties by this reference.

### FIELD OF THE INVENTION

At least some of the disclosed embodiments concern heaters and heating elements used in manufacturing processes, systems, and components. Other possible uses include, but are not limited to, home and industrial heating applications.

### BACKGROUND

The semiconductor industry relies on a variety of systems, processes and chemicals in the manufacture of semiconductor components. Depending upon the application, the components used in chemical process systems can be exposed to a variety of hostile conditions and chemicals. Such conditions may include relatively high temperatures and pressures, and the use of caustic or corrosive chemicals.

In order to provide the heat necessary for chemical and other processes, heaters of various types can be employed. While these heaters have provided relatively good performance in some respects, they nonetheless suffer from various shortcomings.

For example, many of the heaters used in chemical and other processes include heating elements that have a relatively large thermal mass. As a result, such heating elements may require a relatively long time to warm up to operational temperature. Likewise, such heating elements may require a relatively long time to cool down. This slow response time can be problematic, at least because the associated processes with which the heater is used may be lengthened, and relatively slower and/or longer processes are undesirable in manufacturing and processing environments.

The slow response time can present other problems as well. For example, the temperature of the heating element can be relatively difficult to control, and modify. Thus, if a modification to the temperature of the heating element is desired during the performance of a chemical process for example, it may not be possible to implement the change in heating element temperature and process temperature as quickly as needed.

A related problem with typical heaters concerns their power requirements. In particular, the relatively larger thermal mass of the heater can require a significant amount of power to attain, and maintain, a desired operating temperature of the heater. Correspondingly, the heater may be relatively expensive to operate.

As well, at least some heaters can be large and bulky and, as a result, can be difficult to integrate into manufacturing systems that may have space and configuration constraints. Finally, some heaters and heating elements are relatively expensive. In certain cases at least, this can be due to the relatively large size of the heater or heating element.

A further concern with typical heaters, and which is related to some of the points noted above, is that such heaters have a fixed form factor and, as such, are not readily adaptable to different installation configurations. In some cases at least, the fixed form factor is a result of the relatively rigid construction of the heater. Moreover, the fixed form factor requires that a certain amount of space, of a certain configuration, location and orientation, be allocated for installation of the heater. Correspondingly, the fixed form factor of typical heaters may also require that the heater be installed in a particular orientation and/or location relative to other system components.

A related problem is that because it may not be possible to situate the heater close to the component to which the heated fluid is to be supplied, undesirable temperature gradients and/or temperature drops may occur in the heated fluid as it travels from the heater to the component. Such temperature gradients and temperature drops may adversely impact the performance of the component.

In light of problems and shortcomings such as those noted above, it would be useful to provide a fluid heater including a heating element and being flexible in nature so that it can be readily manipulated into various different configurations, orientations, and locations, in order to accommodate the physical constraints of a particular installation. It would also be useful to be able to connect the fluid heater directly, or nearly so, to the component(s) to which the heated fluid is to be supplied.

### ASPECTS OF SOME EXAMPLE EMBODIMENTS

It should be noted that the embodiments disclosed herein do not constitute an exhaustive summary of all possible embodiments, nor does this brief summary constitute an exhaustive list of all aspects of any particular embodiment(s). Rather, this brief summary simply presents selected aspects of some example embodiments. It should further be noted that nothing herein should be construed as constituting an essential or indispensable element of any invention or embodiment. Rather, various aspects of the disclosed embodiments may be combined in a variety of ways so as to define yet further embodiments. Such further embodiments are considered as being within the scope of this disclosure. As well, none of the embodiments embraced within the scope of this disclosure should be construed as resolving, or being limited to the resolution of, any particular problem(s). Nor should such embodiments be construed to implement, or be limited to implementation of, any particular technical effect(s) or solution(s).

Disclosed embodiments are generally concerned with tube heaters and associated heating elements, components and systems. Examples of heating elements, such as resistive carbon elements for example, are disclosed in Appendix A to the '237 Application (herein after, ‘Appendix A’), both of which were incorporated herein by the reference in the Related Applications section hereof. As such, the following discussion primarily concerns example tube heaters that can include, without limitation, any one or more of the heating elements disclosed in Appendix A. More generally, the disclosed tube heaters may include one or more flexible heating elements. As such, the scope of the invention is not limited to the flexible carbon heating elements disclosed in Appendix A and, rather, such heating elements are presented by way of example.

The example disclosed tube heaters can be used in any of a variety of systems, components and applications. As such, this disclosure is intended to be broad in scope and is not limited to any particular configuration(s) of, or application(s) for, the example disclosed tube heaters.

Embodiments within the scope of this disclosure may include, or consist of, any one or more of the following elements, and features of elements, in any combination: any one or more of the heating elements disclosed in Appendix A; a tube heater including a flexible fluid conduit, a flexible containment tube disposed about the fluid conduit, and one or more flexible heating elements disposed between the fluid conduit and the containment tube and in thermal communication with the fluid conduit; a tube heater including a fluid conduit comprising, or consisting of, PFA; a tube heater including a plastic fluid conduit; a tube heater including a plastic containment tube; a tube heater including a connector at one or both ends; a flexible tube heater; a tube heater including a reinforced containment tube; a tube heater including a corrugated containment tube; a tube heater including a fluid conduit in contact with a heating element; a tube heater including a fluid conduit and heating element in contact with an outer surface of the fluid conduit; a tube heater including a fluid conduit in which a portion of a heating element is partially, or completely, embedded; a tube heater including a fluid conduit that is corrosion-resistant, such as to acids and/or bases for example; a tube heater including a fluid conduit, a heating element in thermal communication with the fluid tube, one or more wires connected to the heating element and configured to be connected to an electrical power source, an insulating layer positioned between the wires and the heating element; a microcontroller configured to control the supply of electrical power to a heating element; a tube heater including an integrated microcontroller; a tube heater including one or more sensors; a tube heater including any one or more of an over-temperature sensor, a fluid flow sensor, a temperature sensor, pressure sensor, and a leak sensor; and, a heating element that comprises, or consists of, carbon.

### BRIEF DESCRIPTION OF THE DRAWINGS

The appended drawings contain figures of some example embodiments to further clarify various aspects of the present disclosure. It will be appreciated that these drawings depict only some example embodiments of the disclosure and are not intended to limit the scope of this disclosure in any way. The disclosure will be described and explained with additional specificity and detail through the use of the accompanying drawings.

FIG. 1 is a diagram of an example configuration of a tube heater indicating various elements of the tube heater, and illustrating the flexibility of an example embodiment.

FIG. 2 discloses some attributes of example tube heaters.

FIG. 3 discloses one example embodiment of a tube heater.

FIG. 4 discloses another example embodiment of a tube heater.

FIG. 5 discloses aspects of an example control system for a tube heater.

### DETAILED DESCRIPTION OF SOME EXAMPLE EMBODIMENTS

The present disclosure is generally concerned with tube heaters having one or more heating elements that are flexible in nature. Such flexibility may include the ability to elastically and/or plastically deform so as to achieve, temporarily or permanently as applicable, a particular physical configuration. Example tube heaters include various components that are made of materials that enable the tube heater, as a whole, to be elastically, and/or plastically, formed into a variety of shapes and configurations, such as 45 and 90 degree bends, one or more full loops, and one or more partial loops, for example. Such shapes or configurations can be implemented in two, or three, dimensions. Among other things, such flexibility enables the tube heater to be readily configured to accommodate the size, configuration, and arrangement, of existing structures and components. Further advantageous aspects of example embodiments of the invention are disclosed elsewhere herein.

### A. General Aspects of Some Example Embodiments

In general, the heating elements, heaters and associated systems and components disclosed herein may be used in a variety of different applications, and may be particularly useful in fluid systems for semiconductor manufacturing and/or other chemical processes, although the scope of the invention is not limited to such applications, nor to any particular application. Such fluid systems may employ, for example, deionized (DI) water, corrosive agents and materials including but not limited to acids and bases, gases, other fluids, and combinations of any of the foregoing. Such fluids may be hot, highly pressurized, reactive, and/or pure, fluids.

The temperatures of fluids employed in such systems, such as acids for example, may be anywhere in the range of about 1 degree C. to about 180 degrees C., or in any sub-range falling within that range including, for example, about 100 degrees C. to about 180 degrees C. These temperatures are provided by way of example, and in some instances may be even higher than about 180 degrees C., or lower than 100 degrees C. For example, some systems may employ process fluids that are maintained at a temperature of about 120 degrees C., or higher. As another example, some systems may employ process fluids that may reach temperatures as high as about 200 degrees C. to about 260 degrees C., or higher. Process fluids, and associated fluid systems and components, employed in connection with embodiments of the invention may be pressurized, subjected to a vacuum, and/or unpressurized.

Note that as used herein, “fluid” is intended to be broadly construed and, as such, embraces gases, liquids, combinations of multiple different gases, combinations of multiple different liquids, combinations of one or more gases with one or more liquids, and combinations of one or more gases and/or one or more liquids with one or more solids. As well, it is noted that multiple different phases, such as a gas phase and liquid phase, of a single constituent may exist together at the same time, and such multiple phase combinations are also considered to fall within the scope of a “fluid” as contemplated herein. Consistent with the foregoing discussion, examples of a fluid may comprise, or consist of, one or more gases and/or one or more liquids. As well, embodiments of the invention may be employed with a variety of flow types. For example, a flow type of flowing process fluids and other fluids disclosed herein may be laminar, turbulent, or transitional.

The fluid system components disclosed herein may be constructed with a variety of components and materials including, but not limited to, non-reactive and substantially non-reactive materials, non-metallic and substantially non-metallic materials, rubber, plastics such as polymers, and composites. It should be noted that non-reactive and substantially non-reactive materials embrace a variety of materials, including both metals, such as stainless steel for example, as well as non-metallic materials, such as plastics for example. Examples of the aforementioned polymers may include, but are not limited to, perfluoroalkoxy (PFA) and polytetrafluoroethylene (PTFE), which can be machined or otherwise formed into various components, such as pump bodies, pump heads, pipe, tube, and diaphragms, for example. Fluoroelastomers (FKM), and perfluoroelastomers (FFKM) may also be employed for any of these components. These materials may, or may not, be virgin materials. Some fluid system components, such as a PFA fluid conduit, may come into direct contact with a process fluid, while other fluid system components may not.

Example fluid system components include chemical heaters, such as inline tube heaters for example, as well as tanks and other reservoirs, valves, component connectors, and fluid conduits such as pipe and tube. Components such as chemical heaters can be made of a variety of different materials. Example materials include, but are not limited to, quartz, corundum, and sapphire, whether these are in synthetic or natural form, and any other materials having chemical properties similar to any of the foregoing, including any other substantially non-reactive materials. In certain applications, metals such as steel including stainless steel, copper, titanium, brass, nickel, aluminum, and alloys and combinations of any of the foregoing metals, may be used in the construction of heaters and other components, including the example components disclosed herein. Examples of such alloys include copper-nickel alloys (CNA), and nickel-copper alloys (NCA).

It should be noted that the foregoing components are recited solely for the purpose of illustration. However, the scope of the invention is broad and, as such, embodiments of the invention can be employed to generate heat and transfer heat to any material or materials, regardless of their form or composition. Examples of such materials include, but are not limited to, carbon in any form, carbon compounds, carbon combined with one or more other materials, metals, plastic, rubber, mineral, glass, ceramic, composite, paper and paper based products, fibrous materials, naturally occurring fibers and fabrics or other items made from those, liquids, gases, fluids, synthetic materials, wood and wood based products, chemicals, carbon-based liquids and solids, minerals, plants and plant based materials, any other naturally occurring or man-made materials, or any combination of the foregoing.

### B. Brief Summary of an Example Tube Heater

In general, tube heaters within the scope of this disclosure can have a variety of different physical characteristics and configurations. For example, some example tube heaters include a fluid conduit, which may comprise, or consist of, PFA. The fluid conduit may have, for example, a generally round or oval shaped cross section. More generally however, a fluid conduit can have any cross-sectional shape, including a polygonal shape. The PFA fluid conduit may be clear, colored, or opaque.

The example tube heaters may include one or more heating elements that are flexible in nature such that they are able to elastically deform. In some example embodiments, the one or more heating elements comprise, or consist of, carbon, and are in direct, or indirect, thermal communication with the fluid conduit. In other example embodiments, the one or more heating elements comprise, or consist of, one or more metal(s), one example of which is copper, although other suitable metals or other conductive materials could alternatively be used, and such heating elements can take any suitable form including wire, strips, ribbons, or coils, for example. Heating elements made of different respective materials may be combined in a single implementation of a tube heater.

In some example embodiments, an elongate heating element is sufficiently flexible that it can be elastically bent into a loop having a diameter in a range of about 10 inches to about 14 inches. In one particular example, a tube heater can be elastically bent into a loop of about 360 degrees having a diameter of about 12 inches. In other example embodiments, a tube heater can be elastically bent into a loop of about 360 degrees having a diameter less than about 6 inches. The foregoing are presented only by way of example however.

As well, example elongate heating elements, which can in the form of a flexible strip or flexible rod for example, may be at least as elastically flexible as a ¼″ OD PFA tube. Still other embodiments may be at least as elastically flexible as other sizes of PFA tube. It is noted that it is not necessary that a heating element have an elongate form. For example, and with reference to Appendix A, some embodiments of a heating element can be in the form of a flexible sheet.

It will be appreciated from the examples disclosed in Appendix A that the carbon and carbon-based heating elements disclosed there comprise resistors that comprise, or consist of, carbon. That is, heat generated by application of power to the carbon and carbon-based heating elements is the result of the inherent resistance of the carbon, and other, materials to the flow of current through the carbon or carbon-based heating element. Thus, the carbon and carbon-based heating elements can be considered as resistors, and may be referred to herein as resistive heaters or resistive heating elements.

In any case, when power is applied to the heating element(s), the heating element(s) generate heat that is transferred by any one or more of conduction, convection, and radiation, to a fluid that is present in the fluid conduit. The fluid in the fluid conduit may be still, or flowing. An electrical insulating layer or other insulating element may be provided that implements electrical isolation between the heating element(s) and the wires or other conductors that provide power to the heating elements. Thus, in some embodiments, an electrical insulating layer may be wrapped around the assembly that includes the fluid conduit and the heating elements, and the wires, or other electrical conductors, such as one or more electrically conductive strips or ribbons for example, are then routed along the exterior of the electrical insulating layer.

As well, example embodiments further include a thermal insulating layer that is wrapped, or otherwise disposed, about the assembly that includes the fluid conduit, heating elements, electrical conductors, and electrical insulator. In general, the thermal insulating layer tends to limit the amount of heat transferred out of the fluid. Finally, a containment tube may be provided in which the fluid conduit, heating elements, wires, and electrical insulating layer, are disposed. The containment tube, which may comprise, or consist of, PFA, PTFE, FKM, FFKM, or any other plastic or other material disclosed herein, includes a fluid tight connector at either end that enables the tube heater to be connected to one or more other components. Thus, the containment tube not only protects the internal components of the tube heater from the ingress of foreign matter, but also provides containment in the event of a leak of process fluid from the fluid conduit by confining the leaking process fluid within the tube heater.

As used herein, a fluid tight connector embraces connectors that prevent the escape, at least under normal operating conditions, of both fluids and gases from a containment tube. A liquid tight connector prevents the escape of fluids from a containment tube and would be useful in applications where only liquids will be present in the fluid conduit and containment tube. However, some embodiments of a liquid tight connector would not prevent the escape of gases from a containment tube and thus, would not be employed in applications where there is a chance that gas could escape from the fluid conduit into the containment tube. Thus, in some embodiments at least, the type of connectors employed for the containment tube can depend upon the nature of the process fluids expected to be conveyed through the containment tube during use.

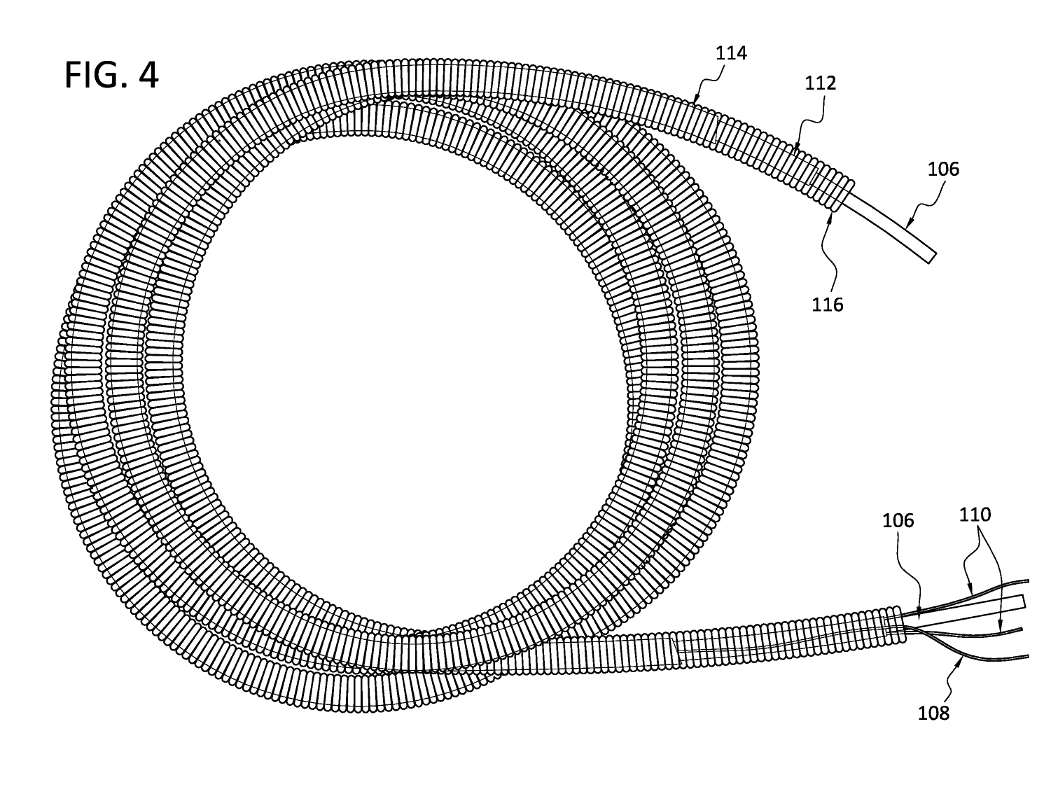

Embodiments such as those described above may be configured with a heating element, conductors, electrical insulator, and containment tube, that each comprise material(s) sufficiently flexible that they and, accordingly, the tube heater as a whole, can be elastically bent to an angle of at least about 30 degrees to about 45 degrees, as well as being elastically and/or plastically bent into loops and other shapes. Bend angles of less than 30 degrees, and bend angles of greater than 45 degrees may be implemented in some embodiments. The aforementioned elements may each be made of a material, or materials, that enable them to be elastically, and/or plastically, formed into a desired shape or configuration. Thus, in some embodiments, the heating element, conductors, electrical insulator, and containment tube may all be sufficiently flexible that they can all be elastically formed, as a unit, into one or more of the example shapes or configurations disclosed herein. One example of this is disclosed in FIG. 4, discussed below, in which the assembled tube heater and its elements, including the heating element, conductors, electrical insulator, and containment tube, are all bent into a loop having a diameter of about 12 inches.

### C. Some Particular Tube Heater Embodiments

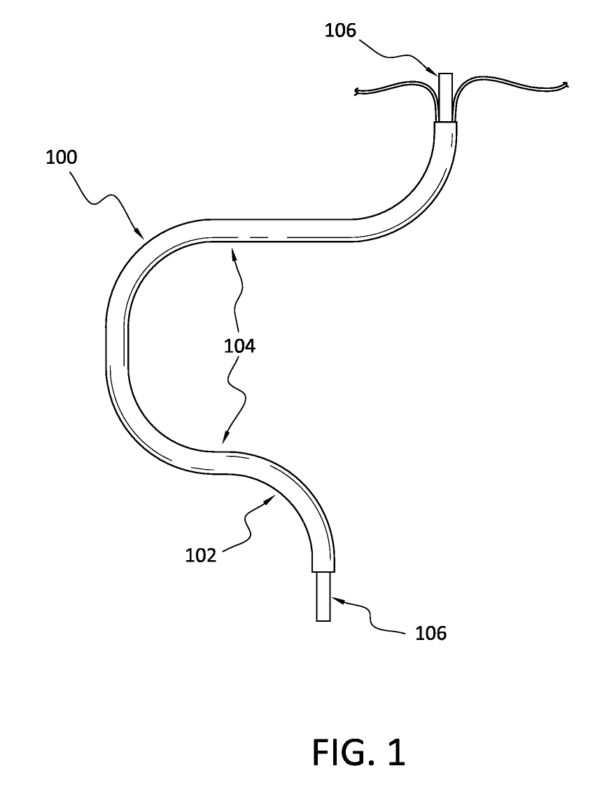

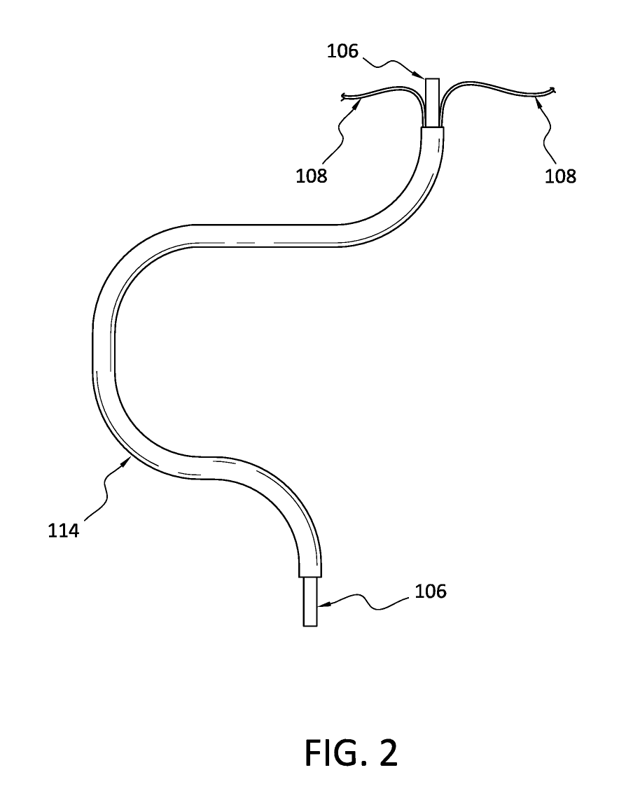

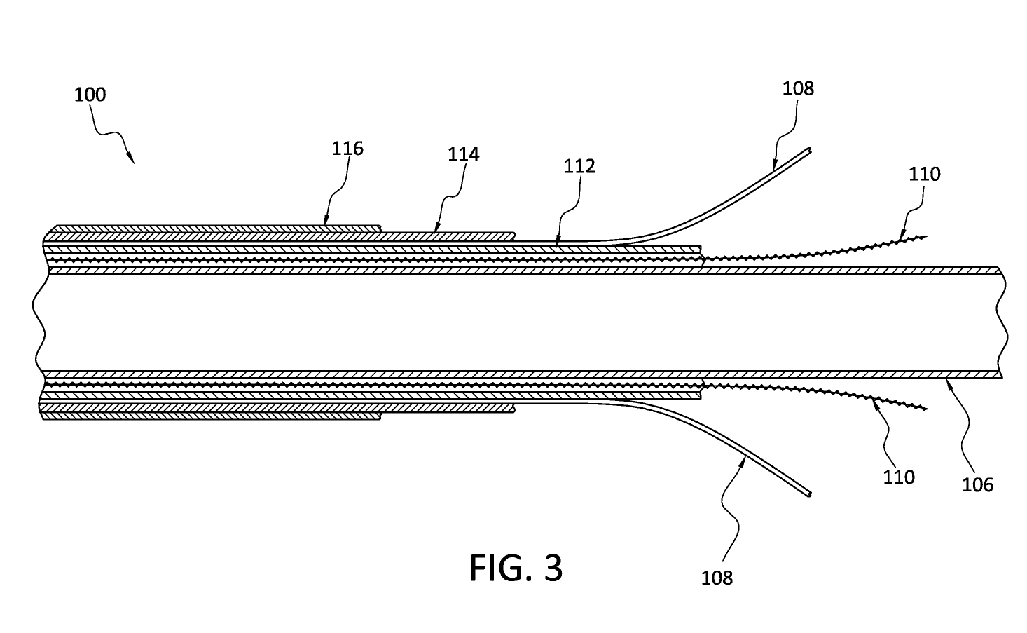

With reference now to FIGS. 1-4, and also with reference to Appendix A, details are provided concerning some example tube heaters, one of which is generally designated at 100 in FIG. 1. In general, the tube heater 100 can have a variety of different geometries, configurations, and features, examples of which are disclosed herein and/or are disclosed in Appendix A (“Potential Heater Configurations”). One or more tube heaters can be connected in series with each other, or in parallel with each other, to one or more fluid system components.

In the particular example disclosed in the Figures, the tube heater 100 can be configured to implement one or more bends 102 of about 90 degrees. While not specifically indicated, bends of less than 90 degrees, and bends of greater than 90 degrees, such as about 180 degrees for example, can also be implemented in the tube heater 100. Moreover, multiple bends can be implemented in series to form another bend. By way of example, a pair of 90 degree bends 102 can be made in series to implement a 180 degree bend 104. There is no limit to the number and size of bends that can be implemented in a particular tube heater 100. As well, there is no limit to the length, diameter, or other dimension, of a particular tube heater 100.

Moreover, while the Figures indicate bends, such as bends 102 and 104 as being implemented in a single plane, that is, in two dimensions, it should be understood that a tube heater 100 may include one or more bends implemented in three dimensions as well, that is, three dimensional bends. As well, two and three dimensional bends can both be implemented in a single tube heater 100. In some example embodiments, a minimum bend radius is defined that can be a function of variables such as the diameter of the tube heater 100, or the OD of the fluid conduit, and the materials used for the tube heater 100 components. Thus, in the example of FIG. 1, a minimum bend radius of about 2 inches is employed, but larger or smaller bend radii can be used in other embodiments.

With continued reference to FIGS. 1-4, further details are provided concerning example components that may be included in a tube heater 100. As shown, the tube heater 100 includes a fluid conduit 106 through which a process fluid that is to be heated can flow. As noted herein, some embodiments of the fluid conduit 106 may comprise, or consist of, PFA. The inside and outside diameter of the fluid conduit 106 can be any size. In one illustrative example, the fluid conduit 106 has an outside diameter (OD) of ¼ inch, although a fluid conduit 106 of a larger, or smaller, size can alternatively be used in other embodiments. Other example sizes of fluid conduit and associated connectors are disclosed in Appendix A. In some embodiments at least, the entire fluid path defined by the tube heater 100 comprises, or consists of, PFA so that process fluid contacts only PFA material during the entire time that the process fluid is present in the tube heater 100.

The size of the fluid conduit 106 can be selected based on a desired flow rate, or range of flow rates, through the tube heater 100. Thus, and as indicated in Appendix A, the liquid flow rate through a tube heater can be specified in liters per minute (LPM), and a gas flow rate through a tube heater can be specified in cubic feet per minute (CFM). One example liquid flow rate that may be implemented in some embodiments of the invention is about 2 LPM. The foregoing are presented only by way of example and are not intended to limit the scope of the invention in any way.

The tube heater 100 additionally includes one or more conductors 108, such as wires or ribbons for example, that are connected to, or otherwise electrically communicate with, one or more heating elements 110. While not specifically shown in the Figures, the conductors 108 may interface directly with, and be connected to, the ends, or other portions, of the heating elements 110, such as the ends of carbon fiber heating elements. More generally, the conductors 108 can be connected, whether directly, or indirectly by way of one or more electrically conductive intervening components, to the heating element(s) 110 in any suitable manner. Adhesives and/or other materials, and/or mechanical connections, may be used to connect the conductors 108 and heating element(s) 110 to each other. The heating elements 110 can be connected to a power supply in series, or in parallel, with each other. The heating elements 110 may be powered by an AC power supply, or a DC power supply.

As noted herein, the heating element(s) 110 can comprise any of the heating elements disclosed in Appendix A. However, the scope of the invention is not limited to those heating elements and extends, more generally, to any type of resistive heating element, that is, a heating element that generates heat, due to electrical resistance of the heating element, when an AC current or DC current is passed through the heating element. As well, resistive heating elements within the scope of the invention include any resistive heating element that is flexible and, as such, can be elastically and/or plastically deformed.

The heating elements employed within a single implementation of a tube heater may all be the same. In other embodiments of a tube heater, heating elements of different sizes and/or configurations may be employed together in a single tube heater. As well, a tube heater may employ only a single heating element, while other embodiments may employ multiple heating elements.

As well, an electrical insulator 112 is provided that is configured and arranged in such a way, with respect to the conductors 108 and the heating elements 110, that the conductors 108 only contact the heating elements 110 at designated connection points, and so that the conductors 108 do not contact each other. This configuration and arrangement of the electrical insulator 112 relative to the conductors 108 and the heating elements 110 may help to prevent problems, such as shorting of the conductors 108. Examples of a suitable electrical insulator, such as an electrically insulating layer, are disclosed in Appendix A. A thermal insulator 114 may also be provided that helps to retain heat in the tube heater 100. Finally, a containment tube 116 encloses all of the aforementioned components. The containment tube 116 may comprise, or consist of, PFA, or any of the other materials disclosed herein.

In some embodiments, the containment tube 116 may be corrugated and/or reinforced, such as with wire for example, to provide durability, and to protect against crushing and crimping. As well, it will be appreciated that such reinforcement, whether implemented as wire or in some other form, is susceptible to plastic deformation. As such, in some embodiments at least, wire or other materials may be employed as part of a tube heater so that the tube heater can be bent, or re-bent, into, and maintained in, a desired configuration.

Various materials can be used for the electrical insulator 112, and the thermal insulator 114. For example, the thermal insulation can comprise ceramic fiber, or an ethylene chlorotrifluoro ethylene (ECTFE) jacket material. Further, the electrical insulator 112 may comprise polyimide tape. The foregoing materials for the electrical insulator 112 and thermal insulator 114 are provided only by way of example. Other suitable materials may alternatively be used.

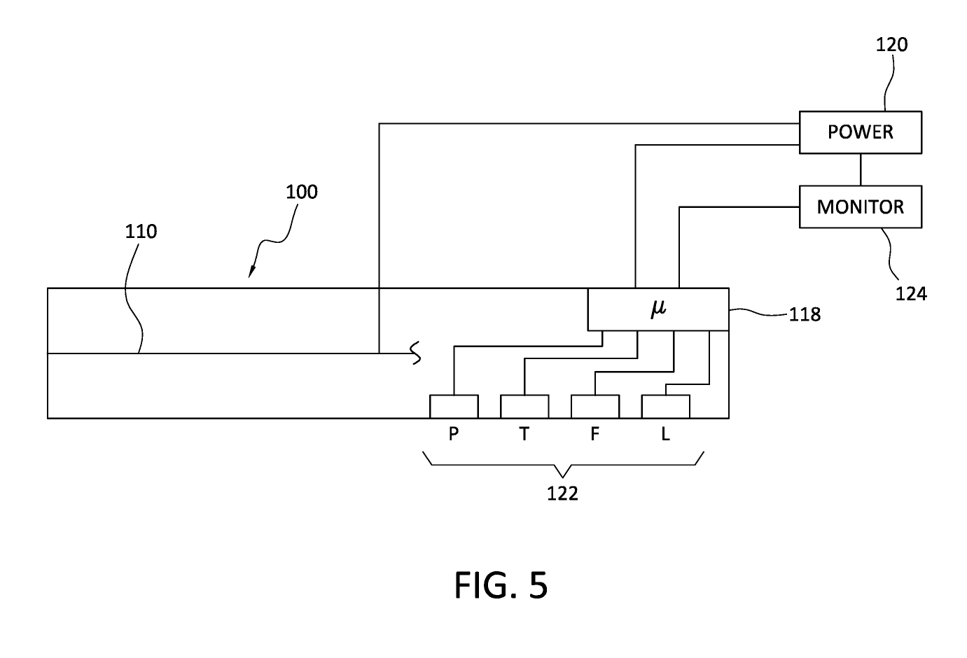

With particular reference now to FIG. 5, embodiments of the tube heater 100 may also include a microcontroller 118 that is programmed, or programmable, to regulate the flow of power to the heating element 110, cut off power to the heating element 110, generate and transmit signals indicating that a leak has been detected inside the tube heater 100, and generate and transmit signals indicating that the temperature of the fluid in the tube heater 100 is too high and/or too low. The microcontroller 118 may comprise one or both of a field programmable gate array(s) (FPGA), and an application specific integrated circuit(s) (ASIC). More generally however, the microcontroller 118 can take any form capable of implementing any combination of the monitoring and control functions disclosed herein.

The microcontroller 118 may be integrated into the tube heater 100. For example, the microcontroller 118 can be embedded in, or attached to, the containment tube 116. Alternatively, the microcontroller 118 can be integrated by being disposed inside the containment tube 116, such as by mounting to the electrical insulator 112 for example. The microcontroller 118 may communicate with an external power supply 120 by hardwire connection or wireless connection conforming to the Bluetooth or any of the 802.11X standards. As noted in Appendix A, the power supply may be single phase, or three phase.

It is noted that the power supply need not be external in all cases and, as such, some embodiments employ a power supply that is integrated into the tube heater 100. In some cases, the power supply can take the form of one or more batteries.

In some embodiments, the microcontroller 118 may communicate with the external power supply 120, and/or other components, using near field communication (NFC), according to one or more NFC protocols. In any case, communication between the microcontroller 118 and the external power supply 120 enables the microcontroller 118 to transmit control signals to the external power supply 120 so as to control the flow of current from the external power supply 120 to the heating element(s) 110. The microcontroller 118 and/or the external power supply 120 may include an on/off switch or similar mechanism that can be used to selectively electrically isolate the external power supply 120 from the microcontroller 118.

In at least some embodiments, the microcontroller 118 can include, or access, non-transitory storage media, such as memory for example, carrying computer executable instructions to control the operation of the power supply 120. In operation, one or more hardware processors (not shown) of the microcontroller 118 can execute those instructions to control the operation of the power supply 120.

One relatively simple algorithm could be used to this end. For example, an over-temperature sensor may generate a signal when the temperature of the process fluid is too high. This signal may be received and processed by the microcontroller and/or processors to generate a control signal. The control signal may then be sent to the power supply, causing the power supply to either shut off power to the heating elements completely, or causing the power supply to reduce the amount of power provided to the heating elements. In the latter case, a closed feedback loop may thus be employed in which the feedback from the over-temperature sensor could be continuously, or periodically, generated and used by the microcontroller to cause adjustments to the amount of power provided by the power supply to the extent needed to establish and maintain an acceptable process fluid temperature.

It is noted that in some instances at least, a temperature gradient may exist in the process fluid in the tube heater. For example, the process fluid at the entrance of the tube heater may be relatively cooler than the process fluid at the exit of the tube heater since the process fluid at the entrance has been in thermal communication with the heating elements a shorter time than the process fluid at the exit. However, such temperature gradients may be acceptable at least so long as the temperature of the process fluid leaving the tube heater is at a desired level, or within a desired range. It is noted that increasing the temperature of the process fluid in the tube heater may increase the pressure of that process fluid.

As the foregoing suggests, the tube heater 100 may include a variety of sensors 122 that are configured to communicate with the microcontroller. Such sensors 122 may be integrated into the tube heater 100 and may include, for example, a temperature sensor such as an over-temperature sensor that detects and reports a temperature of the fluid in the tube heater 100 as well as reporting over-temperature conditions in which the fluid temperature exceeds an allowable temperature, a flow sensor that detects and reports a rate of flow through the tube heater, a fluid pressure sensor, and a leak detection sensor which may be located outside the fluid conduit 106, but inside the containment tube 116. Other example sensors are disclosed in Appendix A hereto. To illustrate, and as indicated in Appendix A, some over-temperature sensors that may be employed in embodiments of the invention include the J-Type T/C, PT1000 (RTD), and PT 100 (RTD) sensors produced by PYROMATION, 5211 Industrial Road, Fort Wayne, In. 46825 (ph. 260.484.2580).

Information obtained from the sensors 122 may be displayed at a monitor 124 that communicates by hardwire or wireless connection with the microcontroller 118, and also used to control the flow of current from the power supply, such as by the example algorithm disclosed herein. Optical fibers may alternatively be used to enable the communications disclosed in connection with the example configuration of FIG. 5.

### D. Advantageous Aspects of Some Embodiments

As will be apparent from the disclosure, one or more embodiments of the invention can provide one or more advantageous and unexpected effects, in any combination, some examples of which are set forth herein. It should be noted that such effects enumerated herein are neither intended, nor should be construed, to limit the scope of the claimed invention in any way. Thus, none of the disclosed embodiments are required to implement any of such advantageous or unexpected effects.

An embodiment of the invention may be advantageous inasmuch as it provides for a tube heater whose flexible configuration can be readily manipulated, such as by bending for example, to suit the constraints imposed by the physical environment where the tube heater is to be employed. As well, an embodiment of the tube heater can be employed with a fluid that is a gas, a liquid, or a combination of a liquid and a gas. As another example, an embodiment of a tube heater includes connections that enable it to be directly connected to the component(s) to which heated fluid is to be provided, as well as directly connected to the component(s) from which the fluid is received by the tube heater. As well, the heating element(s) of an embodiment of the tube heater may have a relatively rapid response time in terms of the speed at which the heating elements can achieve a desired temperature. As another example, a tube heater may employ one or more resistive heating elements that comprise, or consist of, carbon, which can enable fast response times due to the relatively small thermal mass of the carbon heating element(s). Further, an embodiment of the tube heater provides containment functionality in the event of a leak of process fluid inside the tube heater. As well, the PFA construction of the fluid conduit enables an embodiment of the tube heater to be used with a variety of process fluids that must be maintained at a high level of purity. Further, the integration of a microcontroller in an embodiment of the tube heater permits the implementation of a stand-alone tube heater that does not require the use of, or connection to, an external controller. Moreover, the ability to connect an embodiment of the tube heater directly to system components reduces or eliminates the occurrence of unacceptable temperature drops and gradients. Finally, an embodiment of the tube heater includes one or more heating elements that may provide one or more advantages such as are disclosed in Appendix A.

### E. Some Further Example Embodiments

Embodiment 1. A heater, comprising: a heating element that is flexible in nature and substantially comprises carbon; and electrical contacts configured and arranged for electrical communication with the heating element, wherein the heating element generates heat when connected to a flow of electrical current.

Embodiment 2. A tube heater, comprising: a fluid conduit comprising a flexible material; a heater according to embodiment 1, wherein the heating element of the heater is arranged for thermal communication with the fluid conduit; one or more conductors connected to the electrical contacts of the heating element and configured to provide power to the heating element; an insulator configured and arranged to electrically isolate the heating element from the one or more conductors; and a containment tube within which the fluid conduit, heater, conductors, and insulator are disposed.

Embodiment 3. The tube heater as recited in embodiment 2, wherein the fluid conduit comprises, or consists of, PFA.

Embodiment 4. The tube heater as recited in embodiment 2, wherein the heating element is in the form of a fabric wrapped around part, or all, of the fluid conduit.

Embodiment 5. The tube heater as recited in embodiment 2, wherein each of the heating element, conductors, insulator, and containment tube, comprises one or more materials sufficiently flexible that the materials can be bent to an angle of at least about 30 degrees to about 120 degrees.

Embodiment 6. The tube heater as recited in embodiment 2, further comprising a fluid-tight connector at each end of the tube heater.

Embodiment 7. The tube heater as recited in embodiment 6, further wherein the fluid-tight connectors do not include O-rings.

Embodiment 8. The tube heater as recited in embodiment 2, further comprising an integrated microcontroller arranged in series with the conductors, and programmed to control the flow of power to the heating element.

Embodiment 9. The tube heater as recited in embodiment 2, further comprising one or more of an over-temperature sensor, and a leak sensor.

Although this disclosure has been described in terms of certain embodiments, other embodiments apparent to those of ordinary skill in the art are also within the scope of this disclosure. Accordingly, the scope of the disclosure is intended to be defined only by the claims which follow.

What is claimed is:

1. A tube heater, comprising:
a fluid conduit;
a heating element that is in thermal communication with the fluid conduit;
one or more conductors that are in electrical communication with the heating element and are configured to provide power to the heating element;
an electrical insulator configured and arranged to prevent shorting of the one or more conductors; and
a containment tube within which the fluid conduit, heating element, conductors, and electrical insulator are substantially, or completely, disposed.

2. The tube heater as recited in claim 1, wherein the tube heater is elastically deformable into a bend describing an angle that is in a range of at least about 30 degrees to at least about 120 degrees.

3. The tube heater as recited in claim 1, wherein the fluid conduit comprises, or consists of, PFA.

4. The tube heater as recited in claim 1, wherein the heating element has an elongate form.

5. The tube heater as recited in claim 1, further comprising a connector at each end of the tube heater that is configured to enable attachment of the ends of the tube heater to one or more components.

6. The tube heater as recited in claim 5, wherein the connectors do not include an O-ring.

7. The tube heater as recited in claim 1, wherein an entire fluid flow path of the tube heater is defined by the fluid conduit such that any process fluid entering the tube heater contacts only fluid conduit material during the entire time that the process fluid is present in the tube heater.

8. The tube heater as recited in claim 1, wherein the tube heater is fluid tight such that the containment tube contains any fluid that leaks from the fluid conduit.

9. The tube heater as recited in claim 1, further comprising an integrated microcontroller that is connectible to a power supply and programmed to control a flow of power from the power supply to the heating element.

10. The tube heater as recited in claim 9, further comprising an over-temperature sensor, and a leak sensor, both of which are configured to provide feedback to the microcontroller.

11. A tube heater, comprising:
a fluid conduit comprising, or consisting of, PFA;
a plurality of heating elements that each comprise, or consist of, carbon, and the heating elements are in thermal communication with the fluid conduit;
one or more conductors that are in electrical communication with the heating element and are configured to provide power to the heating element;
an electrical insulator configured and arranged to prevent the one or more conductors from contacting each other, and to prevent the one or more conductors from contacting the heating elements except at a location, or locations, where the one or more conductors are connected to the heating elements; and
a containment tube within which the fluid conduit, heating element, conductors, and electrical insulator are disposed.

12. The tube heater as recited in claim 11, wherein the tube heater is elastically deformable into a loop without adverse effect to the structure or operation of the tube heater.

13. The tube heater as recited in claim 11, further comprising a thermal insulating layer disposed between the electrical insulator and the containment tube.

14. The tube heater as recited in claim 11, wherein one of the heating elements has an elongate form.

15. The tube heater as recited in claim 11, further comprising a fluid tight connector at each end of the tube heater that is configured to enable attachment of the ends of the tube heater to one or more components.

16. The tube heater as recited in claim 11, wherein the heating elements are resistive heating elements.

17. The tube heater as recited in claim 11, wherein an entire fluid flow path of the tube heater is defined by the fluid conduit such that any process fluid entering the tube heater contacts only fluid conduit material during the entire time that the process fluid is present in the tube heater.

18. The tube heater as recited in claim 11, wherein the tube heater is configured such that, in use, an inlet side of the tube heater and an outlet side of the tube heater can be offset from each other in two or more dimensions.

19. The tube heater as recited in claim 1, further comprising a microcontroller that is connectible to a power supply and programmed to selectively control a flow of power from the power supply to the heating elements.

20. The tube heater as recited in claim 19, further comprising an over-temperature sensor, and a leak sensor, both of which are configured to provide feedback to the microcontroller.
